(19) United States
(12) Patent Application Publication
(10) Pub. No.: US 2018/0166300 A1
(43) Pub. Date: Jun. 14, 2018

(54) POINT-OF-USE MIXING SYSTEMS AND METHODS FOR CONTROLLING TEMPERATURES OF LIQUIDS DISPENSED AT A SUBSTRATE

(71) Applicant: Lam Research AG, Villach (AT)

(72) Inventor: Philipp Zagorz, Villach (AT)

(21) Appl. No.: 15/377,399

(22) Filed: Dec. 13, 2016

(51) Int. Cl. H01L 21/67; B01F 3/08; B01F 15/00; B08B 3/04; B08B 3/08; B08B 11/02; B05C 11/08; H01L 21/687; H01L 21/66; H01L 21/02

(52) U.S. Cl. CPC H01L 21/67051; B01F 3/088; B01F 15/00207; B01F 15/00344; B08B 3/041; H01L 21/02041; B08B 11/02; B05C 11/08; H01L 21/67248; H01L 21/68714; H01L 22/26; B08B 3/08

(57) ABSTRACT

A liquid dispensing system for treating a substrate is provided and includes a flow controller, pressure regulator, mixing node, liquid mixer, temperature sensor, N dispensers, and system controller. The flow controller receives and controls a flow rate of a first liquid. The pressure regulator receives and controls a pressure of a second liquid. The mixing node mixes the first and second liquid output by the flow controller and pressure regulator to provide a first mixture. The liquid mixer mixes the first mixture and a third liquid to provide a second mixture. The temperature sensor measures a temperature of the second mixture. The N dispensers dispense the second mixture at the substrate. The system controller controls the measured temperature to be between the first and second temperatures by adjusting the flow rate based on the measured temperature and independent of a measurement of a flow rate of the second liquid.

### FIELD

The present disclosure relates to substrate processing systems, and more particularly to temperature control and mixing of fluids dispensed at a substrate.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A point-of-use (PoU) mixing system may be used to dispense liquids on a substrate rotated by a spin chuck. In some examples, the substrate includes a semiconductor wafer. The liquids are combined to provide a mixture, which is dispensed on the substrate. The PoU mixing system includes liquid flow controllers (LFCs) that control flow rates of the liquids and thus concentration levels of the liquids in the resultant mixture. A LFC is provided for each liquid that is supplied.

In certain applications, the PoU mixing system combines liquids to form a first mixture and a second mixture. The first mixture is dispensed onto a top side of the substrate. The second mixture is dispensed onto a bottom side of the substrate. Although the first mixture and the second mixture may include the same types of liquids, the first mixture is distinct from the second mixture since they are mixed and supplied separately. The first mixture is formed by mixing a first set of two or more liquids. The second mixture is formed by mixing a second set of two or more liquids. Each of the LFCs includes a flow meter and a valve. The flow meters measure respective flow rates of the liquids that are supplied. The flow rates of the liquids are measured prior to mixing the liquids to provide the first mixture and the second mixture. The valves are controlled based on the measured flow rates.

The mixtures may include carrier liquids and a spiking liquid. The carrier liquids may include hot deionized water (DIW) and cold DIW. The spiking liquid may include a concentrated acid. While the same types of liquids are combined to form the mixtures, the LFCs used for the first mixture are different than the LFCs used for the second mixture. Therefore, the concentrations of the mixtures may be different. The different concentrations can occur due to errors in the PoU mixing system, such as errors in operation of the LFCs.

The PoU mixing system has limited control of temperatures of the mixtures. When a temperature and/or concentration of the mixture changes, temperatures of the carrier liquids need to be adjusted to compensate for the changes in the mixtures. The PoU mixing system has a long response time for adjusting the temperatures of the carrier liquids. There is a long adjustment delay period from the time when the change in the mixture is detected to the time when the temperatures of the carrier liquids have been adjusted and match predetermined set points.

In addition, the amount of liquid dispensed by the PoU mixing system and the concentration levels of the mixtures affects back-pressures at the LFCs of the chemicals combined to form the spiking liquid. Changes in the back-pressures affect control of flow rates of the liquids that are combined to provide the mixtures. Flow rates of the liquids and concentrations levels of the mixtures are controlled by closed feedback loops, which include the LFCs. To prevent a fault, a redundant flow meter may be used in each fluid channel of the mixtures. If one of the LFCs does not control a corresponding flow rate correctly, the redundant flow meter is then used to control the flow rate. The redundant flow meters increase system costs.

### SUMMARY

A liquid dispensing system for treating a substrate is provided and includes a first flow controller, a pressure regulator, a first mixing node, a liquid mixer, a temperature sensor, N dispensers, and a system controller, where N is an integer greater than or equal to 1. The first flow controller receives a first liquid at a first temperature and controls a flow rate of the first liquid. The pressure regulator receives a second liquid at a second temperature and controls a pressure of the second liquid to a predetermined pressure, where the second temperature is different than the first temperature. The first mixing node mixes the first liquid output by the first flow controller and the second liquid output by the pressure regulator to provide a first mixture. The liquid mixer mixes the first mixture and a third liquid to provide a second mixture. The temperature sensor generates a temperature signal based on a measured temperature of the second mixture. Each of the N dispensers includes a liquid flow controller that dispenses the second mixture at the substrate. The system controller controls the measured temperature to a predetermined temperature between the first temperature and the second temperature by adjusting the flow rate of the first flow controller based on the measured temperature and independent of a measurement of a flow rate of the second liquid.

In other features, a liquid dispensing method for treating a substrate is provided. The method includes: receiving a first liquid at a first temperature at a first flow controller and controlling a flow rate of the first liquid; supplying a second liquid at a second temperature and at a predetermined pressure, where the second temperature is different than the first temperature; and mixing the first liquid output by the first flow controller and the second liquid at a first mixing node to provide a first mixture. The method further includes: mixing the first mixture and a third liquid to provide a second mixture; generating a temperature signal based on a measured temperature of the second mixture; and dispensing the second mixture at the substrate via N dispensers, where N is an integer greater than or equal to 1, and where the N dispensers each include a liquid flow controller to dispense the second mixture. The method further includes controlling the measured temperature to a predetermined temperature between the first temperature and the second temperature by adjusting the flow rate of the first flow controller based on the measured temperature and independent of a measurement of a flow rate of the second liquid.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block and schematic diagram of an example PoU mixing system in accordance with the present disclosure;

FIG. 2 is a functional block and schematic diagram of an example LFC;

FIG. 3 is a functional block and schematic diagram of another example PoU mixing system including liquid supply valves and a valve for changing between single and dual dispensing modes in accordance with the present disclosure;

FIG. 4 is a functional block and schematic diagram of another example PoU mixing system including liquid supply paths for multiple chemicals of a spiking mixture in accordance with the present disclosure; and

FIG. 5 illustrates an example method of operating the PoU mixing system in accordance with an embodiment of the present disclosure.

In the drawings, reference numbers may be reused to identify similar and/or identical elements.

### DETAILED DESCRIPTION

PoU mixing systems and methods according to the present disclosure mix a first carrier liquid, a second carrier liquid, and a spiking liquid to provide a single resultant mixture. The resultant mixture can be dispensed on one or both sides of a substrate. As will be described further below, a flow rate of the first carrier liquid is controlled based on a temperature of the resultant mixture. The second carrier liquid is supplied at a predetermined pressure and temperature.

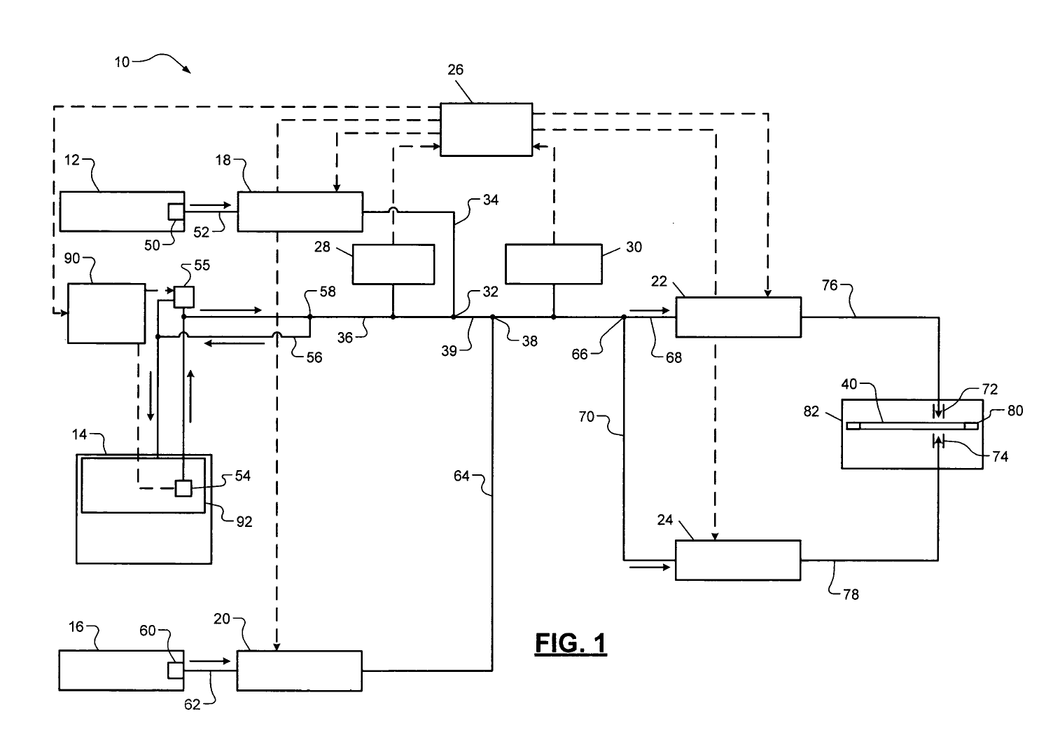

In the following described FIGS. 1-4, solid connecting lines represent fluid channels and dashed connecting lines represent electrical signals.

FIG. 1 shows a PoU mixing system 10 that includes liquid sources 12, 14, 16, LFCs 18, 20, 22, 24, a system controller 26, a pressure sensor 28 and a temperature sensor 30. The liquid sources 12, 14 provide carrier liquids, which are mixed at a node 32 where fluid channels 34, 36 meet. The mixing of the carrier liquids provides a carrier liquid mixture, which is mixed with a spiking liquid provided by the liquid source 16. The carrier liquid mixture is mixed with the spiking liquid at a node 38 to provide a resultant mixture. The nodes 32 and 38 may be referred to as mixing nodes. The node 38 is downstream from the node 32 and receives an output of the node 32 via a fluid channel 39. The resultant mixture is dispensed at a first (or top) side and a second (or bottom) side of a substrate 40. Temperatures and flow rates of the resultant mixture dispensed onto one or more sides of the substrate 40 are controlled via the system controller 26, the temperature sensor 30, and the LFCs 18, 20, 22, 24. As an example, the temperature of the resultant mixture may be between 25-80° C.

The liquid source 12 may include a pump 50 that supplies a first carrier liquid (e.g., DIW) via a fluid channel 52 to the LFC 18. The LFC 18 adjusts a flow rate of the first carrier liquid. The liquid source 14 may include a pump 54 that supplies a second carrier liquid (e.g., DIW) to a pressure regulator 55, which outputs the second carrier liquid to the fluid channel 36. The pressure regulator 55 regulates the pressure of the second carrier liquid to a predetermined pressure. In one embodiment, the first carrier liquid is cold DIW and the second carrier liquid is hot DIW. The temperature of the second carrier liquid is greater than the temperature of the first carrier liquid. The temperature of the first carrier liquid is less than the temperature of the resultant mixture. An example temperature of the second carrier liquid is 80° C. In another embodiment, the first carrier liquid is hot DIW and the second carrier liquid is cold DIW. A LFC is not used to adjust a flow rate of the second carrier liquid provided to the node 32.

A recirculation channel 56 may return a portion of the second carrier liquid from the fluid channel 36 back to the liquid source 14. The recirculation channel 56 is connected to the fluid channel 36 at node 58. In an embodiment, the recirculation channel 56 is provided to circulate the second carrier liquid and prevent cool down of the second carrier liquid in the fluid channels 36 and 58 during idle periods when the second carrier liquid is not flowing through the nodes 32, 36 and/or LFCs 22, 24.

The liquid source 16 may include a pump 60 that supplies the spiking liquid (e.g., a concentrated acid) via a fluid channel 62 to the LFC 20. The LFC 20 adjusts a flow rate of the spiking liquid provided via a fluid channel 64 to the node 38. The resultant mixture output by the node 38 is provided to a node 66 at which portions of the resultant mixture are provided to the LFCs 22, 24 via fluid channels 68, 70, respectively.

The LFCs 22, 24 adjust the flow rates of the portions, which are dispensed onto opposing sides of the substrate 40. This provides accurate and independent control of the flow rates of the resultant mixture dispensed at sides of the substrate 40. As an example, nozzles 72, 74 are shown for dispensing the portions of the resultant mixture at the substrate 40. The nozzles 72, 74 receive the portions of the resultant mixture from the LFCs 22, 24 via fluid channels 76, 78, respectively. The LFC 22, fluid channel 76 and nozzle 72 provide a first dispenser. The LFC 24, the fluid channel 78 and the nozzle 74 provide a second dispenser. The PoU mixing system 10 may be referred to as a liquid dispensing system and may include any number of dispensers. Although two nozzles are shown, one or more nozzles may be included on each side of the substrate 40. In some examples, the substrate 40 may be engaged and rotated by a spin chuck 80 and in a chamber 82. In some examples, the spin chuck includes a spin chuck described in commonly assigned U.S. Pat. No. 6,536,454 or 8,490,634, which are incorporated herein by reference in their entirety.

The pressure sensor 28 detects pressure of the carrier liquid mixture. As an example, the system controller 26 generates a signal based on the pressure and transmits the signal to a carrier liquid controller 90 that is at the liquid source 14. The carrier liquid controller 90 adjusts pressure of the second carrier liquid via the pump 54 and/or the pressure regulator 55. The pump 54 and pressure regulator 55 may receive control signals from the carrier liquid controller 90 based on the pressure detected by the pressure sensor 28. The pressure sensor 28 is used to control pressure within fluid channel 36, which enables LFCs 18, 20, 22, 24 to be operated based on stable predetermined conditions (e.g., maintained predetermined temperature, flow rate and concentration values) of the second carrier liquid. The constant conditions are independent of temperatures, flow rates and concentration set points of the first carrier liquid, the chemicals/spiking liquids and the resultant mixture. This is because the conditions of the second carrier liquid are separately controlled by the carrier liquid controller 90 independent of operations of the system controller 26.

The temperature sensor 30 detects a temperature of the resultant mixture. The system controller 26, based on the temperature, adjusts the flow rate of the first carrier liquid via the LFC 18, and/or the flow rate of the spiking liquid via the LFC 20. The temperature sensor 30 is used to provide a fast response time (e.g., less than 5 seconds(s)) and accurate temperature control (e.g., within 0.5° C. between 25-60° C.) of the resultant mixture.

In one embodiment, the first carrier liquid and the spiking liquid are provided by the liquid sources 12, 16 at predetermined pressures without being temperature controlled. The pressure and temperature of the second carrier liquid is controlled to predetermined values. The temperature of the second carrier liquid may be controlled by the carrier liquid controller 90. A heater and temperature sensor (not shown) may be located in a carrier liquid reservoir 92. The carrier liquid controller 90 may control operation of the heater based on a temperature of the carrier liquid in the carrier liquid reservoir 92. In this embodiment, the controlling of the pressure and temperature of the second carrier liquid occurs at the second liquid source 14. This control of the pressure and temperature allows for precise flow rate, temperature and concentration control of the resultant mixture. In some examples when the second carrier liquid is at a high temperature, high temperature blending accuracy is supported by controlling the temperature of the second carrier liquid and by circulating the second carrier liquid back into the second carrier liquid reservoir 92.

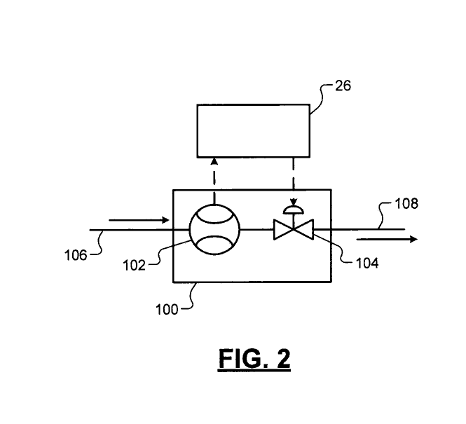

FIG. 2 shows an example LFC 100, which may replace any one of the LFCs 18, 20, 22, 24 of FIG. 1. The LFC 100 may include a flow meter 102 and a regulation valve 104. The flow meter 102 may be upstream from the regulation valve 104. The flow meter 102 may detect a flow rate of a fluid received at the LFC 100 via a fluid channel 106. The system controller 26 may then control the regulation valve 104 based on the detected flow rate. The LFC 100 outputs the received fluid at the adjusted flow rate to a fluid channel 108. The flow meter 102 may be capable of measuring a flow rate of a couple of milliliters per minute to achieve a high turn down ratio (e.g., 1:80) of the LFC 100.

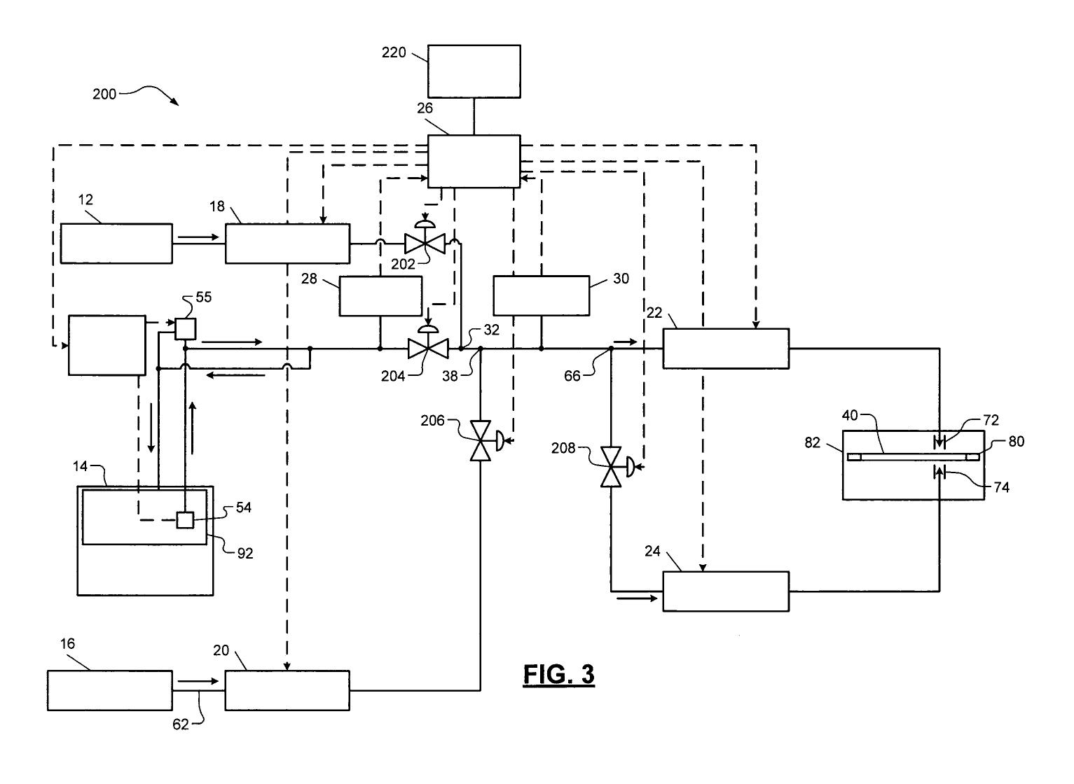

FIG. 3 shows another PoU mixing system 200, which is configured similar to the PoU mixing system 10 of FIG. 1. The PoU mixing system 200 includes the liquid sources 12, 14, 16, LFCs 18, 20, 22, 24, system controller 26, and sensors 28, 30. The PoU mixing system 200 may be used with the nozzles 72, 74 and the spin chuck 80 in chamber 82. The PoU mixing system 200 further includes valves 202, 204, 206, 208. The system controller 26 controls, via the first valve 202, flow of the first carrier liquid from the LFC 18 to the node 32. The system controller 26 controls, via the second valve 204, flow of the second carrier liquid from the liquid source 14 to the node 32. The system controller 26 controls, via the third valve 206, flow of the spiking liquid from the LFC 20 to the node 38. The system controller 26 controls, via the fourth valve 208, flow of a portion of the resultant mixture from the node 66 to the LFC 24. The valve 208 may be used to transition between a single side dispensing mode and a dual side dispensing mode. During the single side dispensing mode, the valve 208 may be closed, such that the resultant mixture is provided only to the top side of the substrate 40. During the dual side dispensing mode, the valve 208 may be open, such that the resultant mixture is provided to both sides of the substrate 40.

The LFCs 22, 24 and the valve 208 control a total amount of liquid and flow rates of the liquid applied on the substrate 40. The total amount of liquid may be supplied to, for example, only the top side of the substrate 40 or to both of the sides of the substrate 40. The total amount of liquid and the flow rates of the liquid may be set based on received inputs from a user of the PoU mixing system 200. The system controller 26 may receive the inputs from the user via a user interface 220.

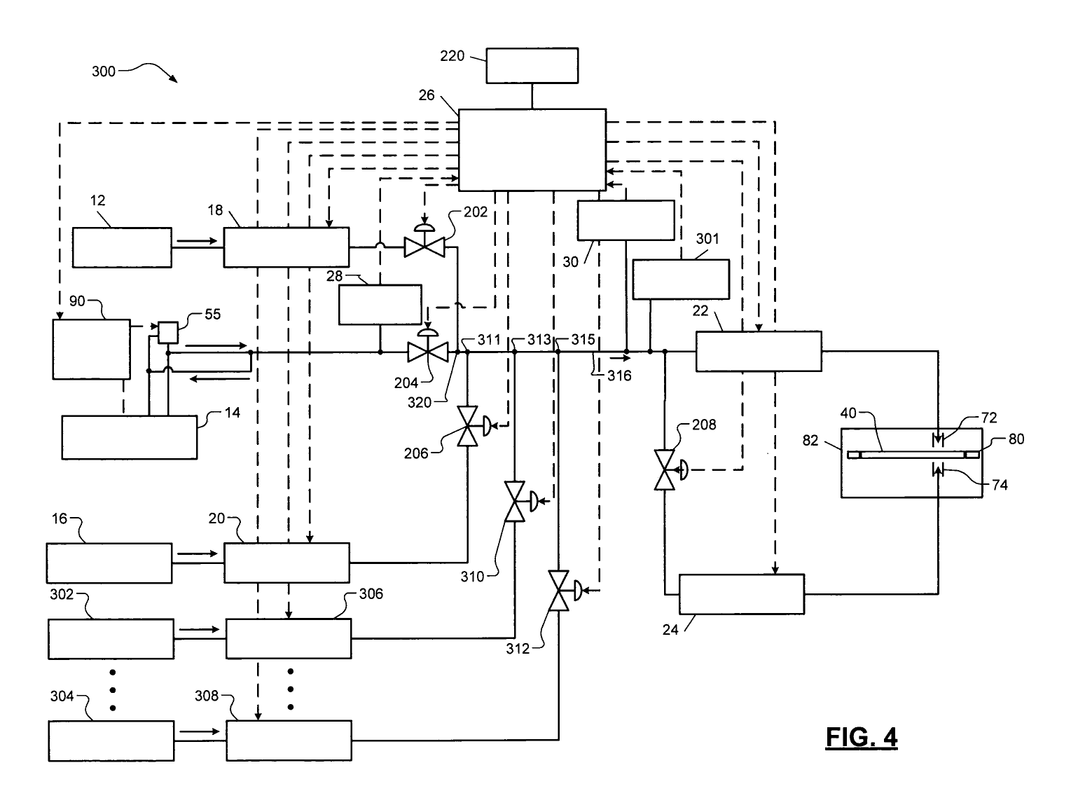

FIG. 4 shows another PoU mixing system 300 including liquid supply paths for multiple chemicals being supplied to provide a spiking mixture. The PoU mixing system 300 is a liquid dispensing system that is configured similar to the PoU mixing system of FIG. 3. The PoU mixing system 300 includes the liquid sources 12, 14, 16, LFCs 18, 20, 22, 24, system controller 26, sensors 28, 30, and valves 202, 204, 206, 208. The PoU mixing system 300 may be used with the nozzles 72, 74 and the spin chuck 80 in chamber 82.

The PoU mixing system 300 further includes one or more additional liquid sources 302, 304 (N liquid sources may be included, where N is an integer greater than or equal to 1), one or more additional LFCs 306, 308, and one or more additional valves 310, 312. The LFCs 20, 306, 308 may be configured as the LFC 100 of FIG. 2 and control flow rates of the chemicals received from the liquid sources 16, 302, 304, respectively. The valves 206, 310, 312 control flow of the chemicals from the LFCs 20, 306, 308 to nodes 311, 313, 315 of a manifold 316. The chemicals may include one or more spiking liquids and/or may be mixed to provide a spiking liquid. The chemicals may be mixed to form a spiking liquid prior to the spiking liquid being mixed with the carrier liquid mixture. The LFCs 20, 306, 308 and the manifold 316 perform as a liquid mixer and may mix the chemicals and/or the spiking liquid(s) with the carrier liquid mixture to provide a resultant mixture. The temperature sensor 30 is downstream from the manifold 316 and detects a temperature of the resultant mixture out of the manifold 316 that is dispensed on the substrate.

The LFCs 20, 306, 308, valves 206, 310, 312, and the manifold 316 may be included in an integrated mixing assembly. The LFCs 20, 306, 308 and valves 206, 310, 312 control one or more mixing ratios of the chemicals received from the liquid sources 16, 302, 304. A mixing ratio refers to proportional relationship(s) between two or more flow rates of two or more chemicals. An example mixing ratio is 1:1:5, where each value of the mixing ratio represents a respective flow rate of one of the chemicals. The mixing ratios may be set based on inputs received via the user interface 220. The mixing ratios may be provided as volumetric ratios received via the user interface 220. The system controller 26 may convert the volumetric ratios into flow rate set points for the LFCs 20, 306, 308.

As an example, three liquid sources (e.g., the liquid sources 16, 302, 304) may provide three chemicals to three LFCs (e.g., the LFCs 20, 306, 308). The three chemicals may be ammonium hydroxide NH₄OH, hydrogen peroxide H₂O₂, and DIW. The liquid flow rates of the three chemicals may be respectively 500 milliliters (mL)/minute (min), 500 mL/min, and 2500 mL/min. This is an example of a 1:1:5 mixing ratio. In one embodiment, the mixing ratio may range from 1:1:5 to 1:1:400. As the flow rate of the third chemical increases, the temperature of the corresponding spiking liquid mixture may increase. The mixing ratio range is provided due to the pressure controlled second carrier liquid and flow rate control of the chemicals. This provides high accuracy at low flow rates of the chemicals of less than 100 mL/min.

In one embodiment, the PoU mixing system 300 uses the fluid channel of the second carrier liquid as a pressure controlled, hot, main fluid channel into which the first (or cold) carrier liquid and the chemicals are injected via the LFCs 18, 20, 306, 308. Constant and stable pressure of the resultant mixture is provided to the sides of the substrate 40 via the LFCs 22, 24. As shown, no LFC is included for the second carrier liquid. The main fluid channel may be oversized (e.g., ½″ inner diameter) for a predetermined flow rate (e.g., 3.5 L/min) of the liquids to be passed through the main fluid line. The second liquid source 14 is effectively controlling the pressure inside the main fluid channel (despite flow dependent pressure losses over installed components). Pressure losses are minimized due to the oversized main fluid channel. The carrier liquid controller 90 (shown in FIG. 2) of the second liquid source 14 performs as a back-pressure controller and recognizes changes in pressure due to fluid being injected into or dispensed out from the main fluid channel. The carrier liquid controller 90 adjusts the pressure to a set point pressure. This pressure adjustment provides predictable and stable pressures for the LFCs 18, 20, 22, 24, 306, 308 independent of fluid being injected into or dispensed out from the main fluid channel. The pressure adjustment also enables high turn down ratios of the chemicals and/or flow rates of the LFCs 20, 306, 208 and a large temperature operating range of the resultant mixture.

The temperature of the resultant mixture is accurately controlled independent of temperatures of the first carrier liquid and temperatures of the chemicals received by the LFCs 20, 306, 308. This holds true if the cold carrier liquid is lower than a set point temperature of the resultant liquid and the hot carrier liquid is higher than the set point temperature of the resultant liquid. In one embodiment, the first carrier liquid is the cold carrier liquid and the second carrier liquid is the hot carrier liquid. In another embodiment, the first carrier liquid is the hot carrier liquid and the second carrier liquid is the cold carrier liquid. The temperatures of the first carrier liquid and the chemicals may not be detected.

The above-described PoU mixing systems 10, 200, 300 of FIGS. 1 and 3-4 use a same fluid channel and/or manifold to mix fluids to generate a resultant mixture that is provided to both sides of a substrate. The same fluid channels and carrier liquid sources are used to provide the carrier liquids for the resultant mixture that is provided to both sides of the substrate. As a result, the concentration level and temperature of a first portion of the resultant mixture provided to a first side of the substrate are the same as or negligibly different than the concentration level and temperature of a second portion of the resultant mixture provided to a second side of the substrate.

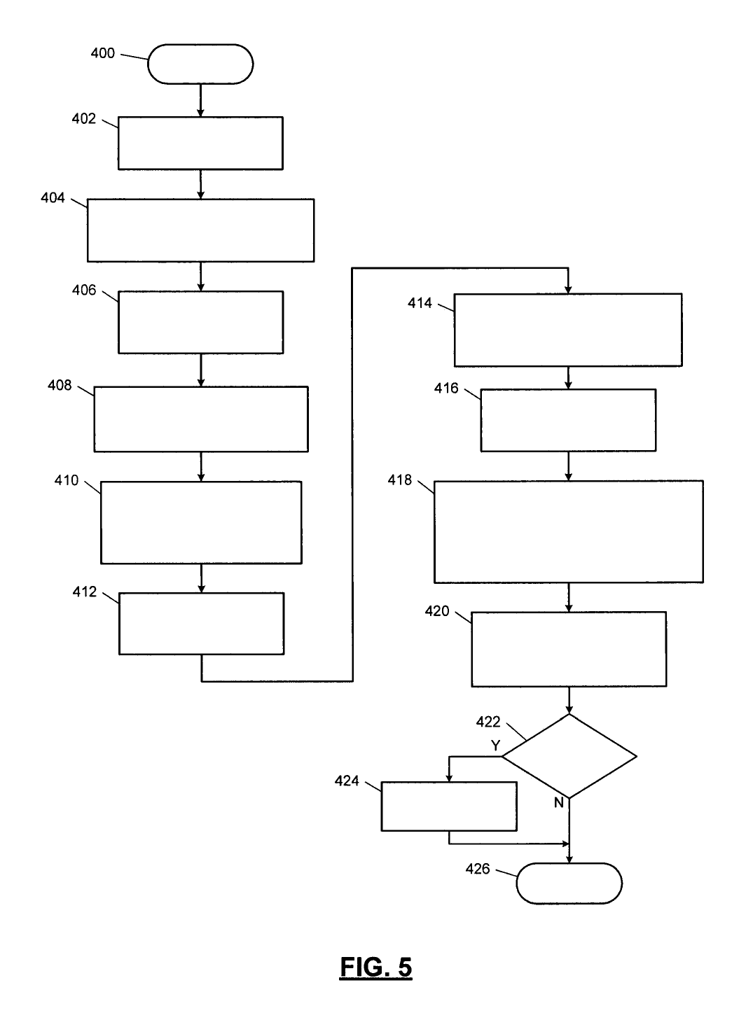

Operations of the PoU mixing systems 10, 200, 300 of FIGS. 1 and 3-4 are further described below with respect to the method of FIG. 5. An example method of operating a PoU mixing system is illustrated in FIG. 5. Although the following operations are primarily described with respect to the implementations of FIGS. 1-4, the operations may be modified to apply to other implementations of the present disclosure. The operations may be iteratively performed.

The method may begin at 400. At 402, a first carrier liquid is supplied from the first liquid source 12. At 404, a second carrier liquid is supplied from the second liquid source 14. The second carrier liquid is supplied at a predetermined pressure and at a predetermined temperature. The second liquid source 14 may maintain the second carrier liquid at a constant pressure and at a constant temperature.

At 406, one or more chemicals are supplied from one or more liquid sources (e.g., the liquid sources 16, 302, 304). The chemicals may include one or more spiking liquids. At 408, the first carrier liquid (e.g. cold DIW) is mixed with the second carrier liquid (e.g. warm DIW) to provide a carrier liquid mixture. This may occur at node 32. Node 32 performs as a first mixer by combining the first carrier liquid with the second carrier liquid.

At 410, the carrier liquid mixture is mixed with the one or more chemicals to provide a resultant mixture. In one embodiment, the chemicals are mixed to provide a spiking liquid, which is mixed with the carrier liquid mixture to provide the resultant mixture. The stated mixing may occur at the node 38 and/or at the manifold 316. Node 38 and the manifold 316 perform as a second mixer by combining the carrier liquid mixture with the one or more chemicals.

At 412, the temperature sensor 30 detects a temperature of the resultant mixture. At 414, the flow meters in the LFCs 22, 24 detect flow rates D₁, D₂, . . . , D_{M} of the portions of the resultant mixture that are dispensed at the sides of the substrate 40, where M is an integer greater than or equal to 1. As an example, the flow rate D₁ may be the flow rate of the portion of the resultant mixture provided to a top side of the substrate 40. The flow rate D₂ may be the flow rate of the portion of the resultant mixture provided to the bottom side of the substrate 40. Flow rates may be determined for any number of portions of the resultant mixture dispensed at each side of the substrate 40. If operating in the single side dispensing mode, then one or more flow rates of one or more portions of the resultant mixture supplied to one side of the substrate 40 is detected. One or more nozzles may dispense the one or more portions of the resultant mixture at one or more points on the side of the substrate 40. If operating in the dual side dispensing mode, then flow rates of the portions of the resultant mixture supplied respectively to nozzles on the sides of the substrate are determined.

At 416, the system controller 26 adjusts the flow rates of the one or more portions of the resultant mixture via the LFCs 22, 24 based on the detected flow rates of the one or more portions and corresponding predetermined set points.

At 418, the system controller 26 may calculate a flow rate S₁ of a spiking liquid/mixture based on a predetermined concentration value c and a sum of the flow rates D₁, D₂, . . . , D_{M} of the one or more portions of the resultant mixture. The concentration value c relates the flow rate S1 to the flow rates D₁, D₂, . . . , D_{M} of the portions of the resultant mixture. The flow rate S₁ of the spiking liquid/mixture may refer to (i) a total flow rate of a single spiking liquid, if only one chemical is provided, or (ii) a flow rate of a mixture of two or more chemicals. The flow rate S₁ of the spiking liquid/mixture may be determined using equation 1.

S₁=c·(D₁+D₂+ . . . +D_{M}) (1)

A flow rate C₂ of the second carrier liquid may not be determined, but may be represented by equation 2, where C₁ is the flow rate of the first carrier liquid.

C₂=(D₁+D₂+ . . . D_{M}) (2)

The flow rate C₂ provides the balancing uncontrolled portion of equation 2, whereas the flow rates D₁, D₂, . . . , D_{M}, and C₁ are controlled. The flow rate and back-pressure of C₂ are automatically adjusted since the amount of supplied input liquid (i.e. the amount of the carrier liquids and the chemicals/spiking liquids) is equal to the amount of output liquid (i.e. the amount of the resultant mixture).

At 420, the system controller 26 adjusts a flow rate of the first carrier liquid based on an algorithm, tables, system models, and/or one or more of the parameters disclosed herein. The LFC 18 and/or the valve 202 control flow of the first carrier liquid based on the temperature of the resultant mixture. The first carrier liquid is injected into the second carrier liquid to achieve a set point temperature of the carrier liquid mixture. The set point temperature may be received as an input via the user interface 220.

In one embodiment, the flow rate of the first carrier liquid is adjusted based on the temperature of the resultant mixture and an algorithm, equation, and/or table relating the flow rate of the first carrier liquid to the temperature. The flow rate of the first carrier liquid may be adjusted based on a predetermined temperature set point for the resultant mixture. The algorithm may account for flow dependent temperature losses. In another embodiment, the flow rate of the first carrier liquid is adjusted based on: user inputs and/or set points for flow rates of the portions of the resultant mixture, flow rates of the chemicals/spiking liquids, a target temperature of the resultant mixture; and/or one or more measured parameters.

The measured parameters may include a temperature of the first carrier liquid, a temperature of the second carrier liquid, temperatures of the chemicals/spiking liquids, the flow rate C₁ of the first carrier liquid, the flow rates D₁, D₂, . . . , D_{M} of the portions of the resultant mixture, and/or the flow rates of the chemicals/spiking liquids. Additional temperature sensors may be included to detect temperatures of the first carrier liquid, the second carrier liquid, and chemicals/spiking liquids. In one embodiment, the temperatures of the first carrier liquid, the second carrier liquid, and chemicals/spiking liquids are estimated based on the temperature of the resultant mixture and the flow rates C₁, C₂, and D₁, D₂, . . . , D_{M}. The measured parameters may include a flow rate of the carrier liquid mixture. A LFC and/or flow meter may be connected to measure a flow rate of the carrier liquid mixture being received by the manifold 316, as described above.

At 422, system controller 26 compares a sum of the inlet flows (e.g., a sum of a flow rate of the carrier liquid mixture and flow rates of the chemicals) received by, for example, the manifold 316 to a sum of dispense flows (e.g., a sum of the flow rates of the portions of the resultant mixture) output from the manifold 316. If the sum of the inlet flows does not match the sum of the outlet flows and/or the sum of the inlet flows is more than a predetermined range from the sum of the outlet flows, then the system controller 26 may determine a fault exists. The fault may be associated with one of the LFCs 18, 20, 22, 24, 306, 308. The fault may be indicated via the user interface 220 to a user. Detecting a fault in this manner does not require use of an inline concentration monitor and/or redundant flow meters. If a fault exists, operation 424 may be performed; otherwise the method may end at 422 as shown or return to task 402. At 424, a countermeasure may be performed, such as placing the system in an idle state and preventing further dispensing of liquids at the substrate 40.

The above-described method allows the system controller 26 to have control over a wide range of temperatures for the resultant mixture. The temperature range is limited by the temperatures, flow rates and pressures of the first carrier liquid, the second carrier liquid, and the chemicals/spiking liquids. The temperature range is also limited by temperature losses to the environment via system components. A temperature of the resultant mixture is based on a relationship between a cold (or first) carrier liquid and a hot (or second) carrier liquid. For example, if a high temperature of the resultant mixture is requested, a flow of a cold (or first) carrier liquid may be low and in turn a flow of a hot (or second) carrier liquid is high. On the other hand, if a low temperature of the resultant mixture is requested, the flow of the cold carrier liquid is high and in turn the flow of the hot carrier liquid is low.

The above-described examples include a temperature sensor and LFCs that are used to control a temperature and flow rates of a resultant mixture, which is dispensed at a substrate. The pressure and temperature of a second carrier liquid may be accurately controlled and supplied to a main fluid channel, which is at a predetermined temperature. Due to the accurately controlled pressure in the main fluid channel, injection of a first carrier liquid and chemicals of a spiking liquid and dispense of a resultant mixture at the substrate are precise and predictable. This enables large turn down ratios of the first carrier liquid and chemicals. Additionally, the systems operate as feedback control systems due to detection of parameters, such as temperature and pressure, which enables precise temperature control of the resultant mixture within a predetermined operating temperature range (e.g., 25-80° C.).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, substrate transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a substrate.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a spin-rinse chamber or module, a clean chamber or module, a bevel edge etch chamber or module, and any other semiconductor processing systems that may be associated or used in the fabrication and/or manufacturing of semiconductor substrates.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of substrates to and from tool locations and/or load ports in a semiconductor manufacturing factory.

What is claimed is:

1. A liquid dispensing system for treating a substrate, comprising:
a first flow controller to receive a first liquid at a first temperature and control a flow rate of the first liquid;
a pressure regulator to receive a second liquid at a second temperature and to control a pressure of the second liquid to a predetermined pressure, wherein the second temperature is different than the first temperature;
a first mixing node that mixes the first liquid output by the first flow controller and the second liquid output by the pressure regulator to provide a first mixture;
a liquid mixer that mixes the first mixture and a third liquid to provide a second mixture;
a temperature sensor to generate a temperature signal based on a measured temperature of the second mixture;
N dispensers each including a liquid flow controller to dispense the second mixture at the substrate, where N is an integer greater than or equal to 1; and
a system controller to control the measured temperature to a predetermined temperature between the first temperature and the second temperature by adjusting the flow rate of the first flow controller based on the measured temperature and independent of a measurement of a flow rate of the second liquid.

2. The liquid dispensing system of claim 1, wherein the system controller further controls the measured temperature based on flow rates of the N dispensing flow controllers.

3. The liquid dispensing system of claim 1, wherein the liquid mixer comprises:
M flow controllers to receive M liquids and control M flow rates of the M liquids, where M is an integer greater than or equal to 1, and wherein one of the M liquids includes the third liquid; and
a second mixing node to mix the first mixture and one or more of the M outputs of the M flow controllers to provide the second mixture.

4. The liquid dispensing system of claim 3, wherein the system controller is configured to control the M flow rates of the M flow controllers based on a predetermined concentration value corresponding to the M liquids and a sum of flow rates of the N dispensing flow controllers of the N dispensers.

5. The liquid dispensing system of claim 3, further comprising M valves arranged between the M flow controllers and the liquid mixer.

6. The liquid dispensing system of claim 1, wherein the system controller is configured to control the measured temperature independent of measurements of the first temperature and the second temperature.

7. The liquid dispensing system of claim 1, further comprising a valve arranged between the first flow controller and the first mixing node.

8. The liquid dispensing system of claim 1, further comprising a valve arranged between the pressure regulator and the first mixing node.

9. The liquid dispensing system of claim 1, further comprising a valve arranged between the liquid mixer and a second one of the N dispensers, wherein N is greater than one.

10. The liquid dispensing system of claim 1, wherein the first flow controller comprises:
a valve; and
a flow meter configured to (i) detect the flow rate of the first liquid, and (ii) based on the flow rate of the first liquid, control the valve to adjust the flow rate of the first liquid.

11. The liquid dispensing system of claim 1, wherein:
the first liquid includes water;
the second liquid includes water; and
the third liquid includes a concentrated acid.

12. A system comprising:
the liquid dispensing system of claim 1; and
a spin chuck configured to engage with the substrate, wherein the substrate is rotated while being supported by the spin chuck and while the substrate is treated by the second mixture from at least one of the N dispensers.

13. A liquid dispensing method for treating a substrate, comprising:
receiving a first liquid at a first temperature at a first flow controller and controlling a flow rate of the first liquid;
supplying a second liquid at a second temperature and at a predetermined pressure, wherein the second temperature is different than the first temperature;
mixing the first liquid output by the first flow controller and the second liquid at a first mixing node to provide a first mixture;
mixing the first mixture and a third liquid to provide a second mixture;
generating a temperature signal based on a measured temperature of the second mixture;
dispensing the second mixture at the substrate via N dispensers, where N is an integer greater than or equal to 1, and wherein the N dispensers each include a liquid flow controller to dispense the second mixture; and
controlling the measured temperature to a predetermined temperature between the first temperature and the second temperature by adjusting the flow rate of the first flow controller based on the measured temperature and independent of a measurement of a flow rate of the second liquid.

14. The liquid dispensing method of claim 13, further comprising controlling the measured temperature based on flow rates of the N dispensing flow controllers.

15. The liquid dispensing method of claim 13, further comprising:
receiving M liquids at M flow controllers and controlling M flow rates of the M liquids, where M is an integer greater than or equal to 1, and wherein one of the M liquids includes the third liquid; and
mixing, via a second mixing node, the first mixture and one or more of the M outputs of the M flow controllers to provide the second mixture.

16. The liquid dispensing method of claim 15, further comprising controlling the M flow rates of the M flow controllers based on predetermined concentration value corresponding to the M liquids and a sum of flow rates of the N dispensing flow controllers of the N dispensers.

17. The liquid dispensing method of claim 13, further comprising controlling the measured temperature independent of measurements of the first temperature and the second temperature.

18. The liquid dispensing method of claim 13, further comprising:
detecting the flow rate of the first liquid via a flow meter; and
based on the flow rate of the first liquid, controlling a valve to adjust the flow rate of the first liquid,
wherein the first flow controller comprises the flow meter and the valve.

19. The liquid dispensing method of claim 13, wherein:
the first liquid includes water;
the second liquid includes water; and
the third liquid includes a concentrated acid.

20. The method of claim 13, further comprising:
engaging with the substrate via a spin chuck; and
rotating the substrate while the substrate is treated by the second mixture from at least one of the N dispensers.
